(19) United States
(12) Patent Application Publication
(10) Pub. No.: US 2006/0147749 A1
(43) Pub. Date: Jul. 6, 2006

(54) Organic polymer light emitting diode device and applied display

(76) Inventors: Hsin-Fei Meng, Hsinchu (TW); Sheng-Fu Horng, Hsinchu (TW); Chia-Hsun Chen, Hsinchu (TW); Je-Ping Hu, Hsinchu (TW); Chien-Shu Hsu, Hsinchu (TW); Kuo-Tong Lin, Hsinchu (TW)

Correspondence Address: RABIN & Berdo, PC, 1101 14TH STREET, NW, SUITE 500, WASHINGTON, DC, 20005, US

(21) Appl. No.: 11/220,668

(22) Filed: Sep. 8, 2005

(30) Foreign Application Priority Data
Dec. 30, 2004 (TW) 93141532

(51) Int. Cl. H01L 51/50; H05B 33/12

(52) U.S. Cl. 428/690; 428/917; 428/212; 313/504; 313/506; 313/112; 257/89; 257/98; 257/E51.022; 257/E51.027

(57) ABSTRACT

A polymeric light emitting diode (PLED) device comprises: a substrate; a positive electrode formed above the substrate; a hole transportation layer formed above the positive electrode; an organic light emitting composite layer formed above the hole transportation layer, comprising a plurality of organic light emitting layers, wherein every organic light emitting layer has an polymeric host material with a higher energy gap, and at least one of the organic light emitting layers is doped with an polymeric material with a lower energy gap; and a negative electrode formed above the organic light emitting composite layer.

### BACKGROUND

1. Field of Invention

The invention relates to an organic light emitting diode (OLED) device and applied display, and in particular to a polymeric light emitting diode (PLED) device and applied display.

2. Related Art

Organic light emitting diodes (OLED) have several advantages, such as small size, long life span, low driving voltage, high responding speed, good shock resistance and low cost for large screen display production, which makes them suitable for an applications that need to be light and thin. If the efficiency of the white light OLED can be further improved, it would be very applicable for a flat display, especially as a backlight source of a large screen LCD display that combines with color filters to produce various colors. Thus the development of a large screen white light OLED device is very important for the development of the full color flat display industry (especially for the LED display industry).

Luminescent materials used in OLEDs include two types: one is polymeric and another is small molecule material. The small molecule type of OLED has brilliant white light brightness, but its cost of mass production is too high. Therefore, presently the key topic is how to improve the luminescence efficiency of low cost PLED.

At present, most techniques used in OLED to produce white light use small molecules, such as the technique disclosed in U.S. Pat. No. 6,521,360. Please refer to FIG. 1A and FIG. 1B. In the drawings, the light emitting layer 120 consists of at least two sub-light emitting layers 122 and 124 for forming an OLED device 100 with mixed light. The OLED device 100 includes a substrate 102, a positive electrode 104, a hole transportation layer 112, a light emitting layer 120 consisting of at least two sub-light emitting layers 122 and 124, an electron transportation layer 114 and a negative electrode 108. At least one of the sub-light emitting layers is based on the material of the electron transportation layer (such as DPBI). Both of the sub-light emitting layers are doped with the same luminescent materials (such as PDBT), but in different concentrations. The color obtained is the combination of lights emitted from all light emitting layers; the brightness obtained is between 240˜590 cd/m² as 20 volts of bias is applied. However, the operation voltage is high and the brightness obtained is not enough. Furthermore, because a three-color mixture is not easily obtained from the adjustment of doped concentration of single luminescent material, a white light with tri-color is not easily obtained from this prior art.

Another method to produce white light by small molecules is disclosed in U.S. Pat. No. 6,720,092. Please refer to FIG. 2, which shows an OLED device having higher luminescence efficiency and a stabilizer process. The OLED 200 uses a light emitting layer comprising a yellow light emitting layer 241 and a blue light emitting layer next to each other. The OLED device 200 includes a substrate 210, a positive electrode 220, a hole injection layer 230, a hole transportation layer 240, a yellow light emitting layer 241, a blue light emitting layer 250, an electron transportation layer 260 and a negative electrode 270. The yellow light emitting layer 241 has rubrene materials, and the blue light emitting layer 250 is next to the yellow light emitting layer 241. In order to control the color mixed from the two lights, the yellow light emitting layer is evaporated on the blue light emitting layer by careful orientation and composition distribution controlling. A compensated white light is then obtained with an efficiency of 3.6 cd/A under a test condition of 6.5V and 160 mA/cm². However, this technique needs an additional evaporating process and only a compensated white light can be obtained. It cannot emit tri-color white light required in the backlight industry.

According to the techniques described above, most white light in organic light emitting material are made by multiple layers comprised with the small molecular materials. A large screen flat display is the main stream of technical development in the future. However, the above methods cannot satisfy the requirements due to the problems of doping concentration uniformity in the evaporating process, and the orientation of the large screen. Because polymeric light emitting material is more suitable to the large screen process than to the small molecular material process, developing a structure or process using a polymer material to emit high efficiency white light is helpful for accelerating the development of the industry.

### SUMMARY

The major objective of the invention is to provide a polymeric light emitting diode (PLED) device and applied display, which provide higher brightness of various colors, low cost and is applicable for large screen displays.

Another objective of the invention is to provide a polymeric light emitting diode (PLED) device and applied display, which provide higher brightness and lower cost of compensated or three-color white lights, and is applicable for large screen displays.

In order to achieve the above objectives, the disclosed polymeric light emitting diode (PLED) device comprises: a substrate; a positive electrode formed above the substrate; a hole transportation layer formed above the positive electrode; an organic light emitting composite layer formed above the hole transportation layer, comprising a plurality of organic light emitting layers, wherein every organic light emitting layer has a polymeric host material with a higher energy gap, and at least one of the organic light emitting layers is doped with a polymeric doping material with a lower energy gap; and a negative electrode formed above the organic light emitting composite layer.

In order to achieve the above objective, a display using a polymeric light emitting diode (PLED) device comprises: a substrate; a positive electrode is formed above the substrate; a hole transportation layer formed above the positive electrode; an organic light emitting composite layer formed above the hole transportation layer, comprising a plurality of organic light emitting layers, wherein every organic light emitting layer has an polymeric host material with a higher energy gap, and at least one of the organic light emitting layers is doped with a polymeric doping material with a lower energy gap; a negative electrode formed above the organic light emitting composite layer; and a color filter formed above the substrate or the negative electrode for filtering light produced by the organic light emitting composite layer and for penetrating a specific wavelength of light.

The polymeric host material with a higher energy gap can be a blue polymeric material. The polymeric doping material with a lower energy gap can be a reddish polymeric material. There are at least two organic light emitting layers doped with two different polymeric doping materials with lower energy gaps. For example, one can be a reddish polymeric material and another can be a green polymeric material.

The organic light emitting composite can include three organic light emitting layers having the same polymeric host materials with a higher energy gap, and two of them have polymeric doping materials with a lower energy gap.

The polymeric host material with a higher energy gap can be a blue polymeric material. One polymeric material doped with a lower energy gap can be a blue-green polymeric material. Another polymeric material doped with a lower energy gap can be a reddish polymeric material.

In summary, a polymeric light emitting diode (PLED) device and applied display according to the invention provide higher brightness of various colors, low cost and can be applied to a large screen display.

### BRIEF DESCRIPTION OF THE DRAWINGS

FIGS. 1A and 1B are diagrams showing the white light OLED of U.S. Pat. No. 6,521,360;

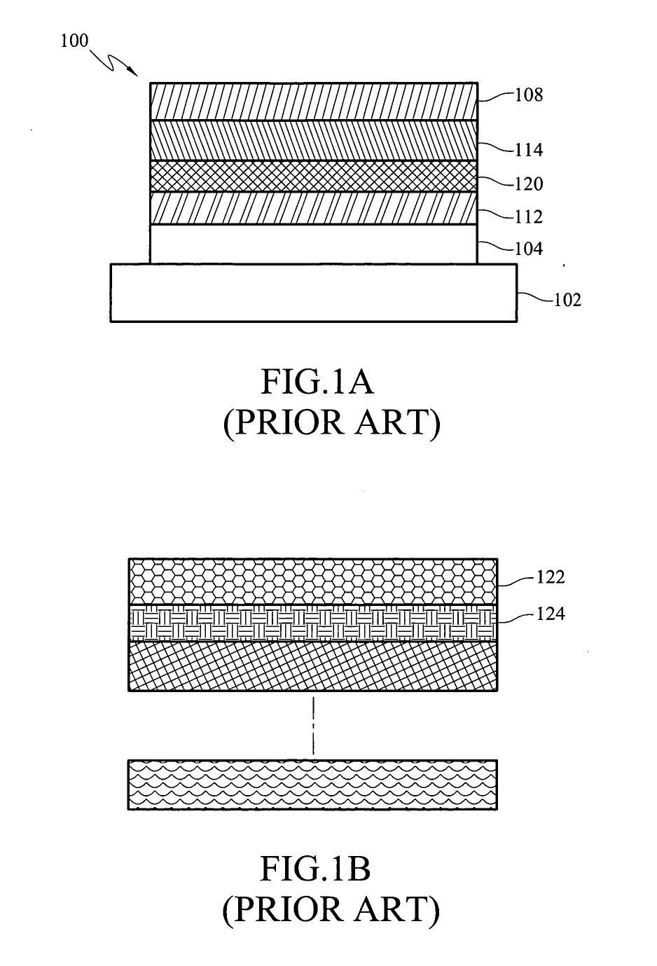

FIG. 2 is a diagram showing the white light OLED of U.S. Pat. No. 6,720,092;

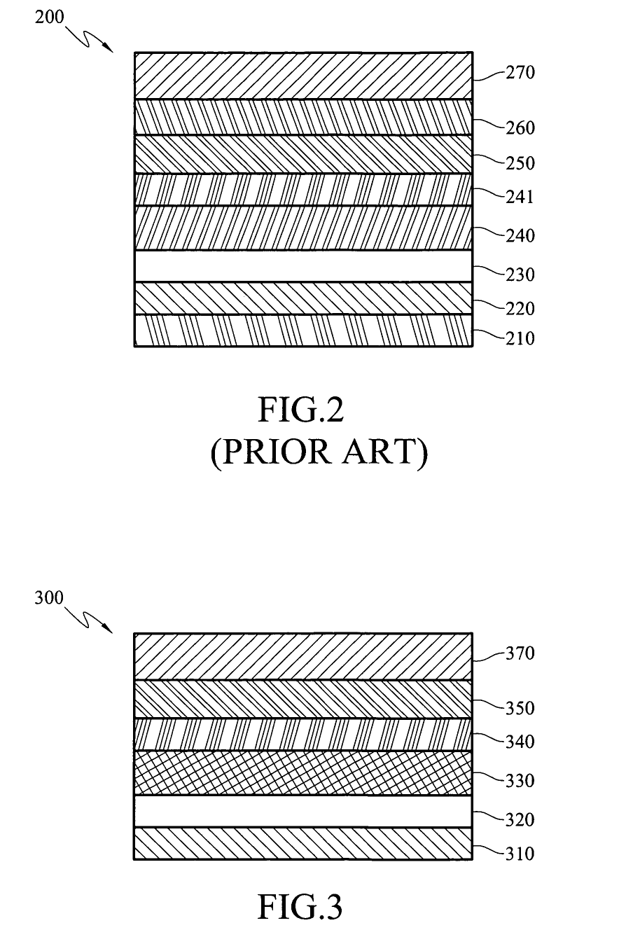

FIG. 3 shows the first preferred embodiment of the PLED device according to the invention;

FIG. 4 shows the second preferred embodiment of the PLED device according to the invention;

FIG. 5 shows the third preferred embodiment of the PLED device according to the invention; and

FIGS. 6 to 8 show luminescence spectrums of working examples 1˜3 for FIG. 3 to 5.

### DETAILED DESCRIPTION

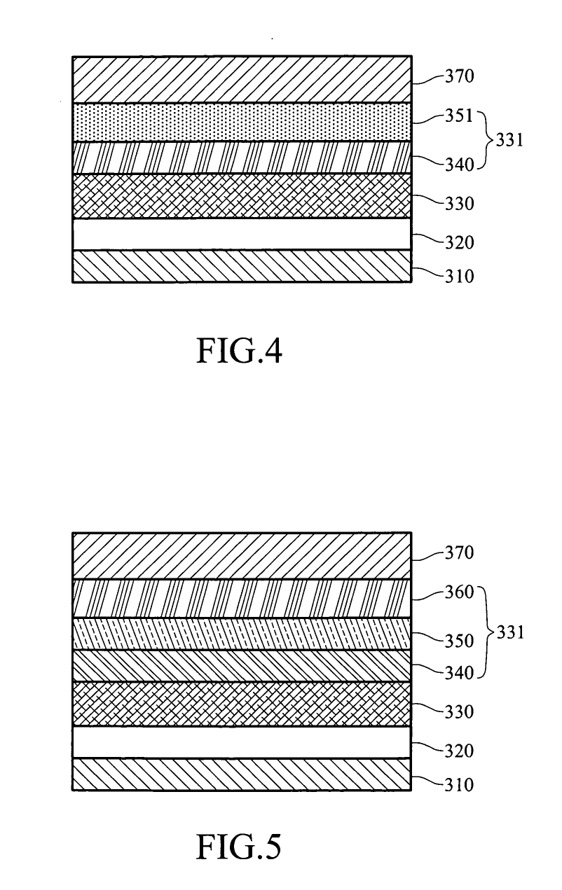

Please refer to FIG. 3, showing the first preferred embodiment of a polymeric light emitting diode (PLED) device according to the invention. The PLED device 300 includes a substrate 310, a positive electrode 320, an organic hole transportation layer 330, an organic light emitting composite 331, and a negative electrode 370. The organic light emitting composite 331 includes at least two organic light emitting layers 340 and 350, which are disposed between the organic hole transportation layer 330 and the negative electrode 370. When a voltage is applied between the positive electrode 320 and the negative electrode 370, the positive electrode 320 injects holes into the hole transportation layer 330 and combines with electrons injected from the negative electrodes 370 through the organic light emitting composite 331 to emit light.

The substrate 310 is electrically isolated and can be a transparent substrate or an opaque substrate according to requirements. If a light is to penetrate the substrate 310, the substrate 310 consists of a transparent material, such as glass, quartz, or plastic. If a light is to penetrate the electrodes 370, the substrate 310 can be based on opaque materials, such as semiconductor materials or ceramics. Of course, the design of the structure must satisfy the requirements of emitting light.

The positive electrode 320 consists of a conductive and transparent material if a light is to penetrate the substrate 310. However, if light emits through the upper electrode 370, the transparent property does not matter to the positive electrodes 320. The positive electrodes 320 are selected from a metal or a metal compound with a higher work function. The metals include aurum, iridium, palladium, or platinum. The conductive and transparent materials include metal oxides, nitrides such as a gallium nitride, selenides such as a zinc selenide, or sulphides such as a zinc sulphide. Appropriate metal oxides include indium-tin oxide (ITO), indium-zinc oxide (IZO), aluminum-zinc oxide (AZO), tin oxide, magnesium-indium oxide, fluorine-tin oxide, nickel-tungsten oxide and cadmium-tin oxide.

The hole transportation layer 330 consists of a polymer conductive material, such as PEDOT.

The organic light emitting composite 331 is used for combining electrons and holes to emit light. In U.S. Pat. No. 6,521,360, this structure includes many light emitting layers based on the materials of electron transportation layers and are doped with different concentrations of luminescent materials. In U.S. Pat. No. 6,720,092, this structure includes a light emitting layer of yellow luminescent materials and alight emitting layer of blue luminescent materials.

In the first embodiment of the invention, an organic light emitting composite 331 including two organic light emitting layers is used as an example. Both of the first organic light emitting layer 340 and the second organic light emitting layer 350 use the same polymeric light emitting materials with a higher energy gap as a host material. The first organic light emitting layer 340 is doped by a polymeric light emitting material with lower energy. For example, the polymeric light emitting host material can be a blue polymer light emitting material and the polymeric light emitting doped material can be a reddish polymer light emitting material, such that the lights from the first organic light emitting layer 340 and the second organic light emitting layer 350 compensate for each other and produce white light.

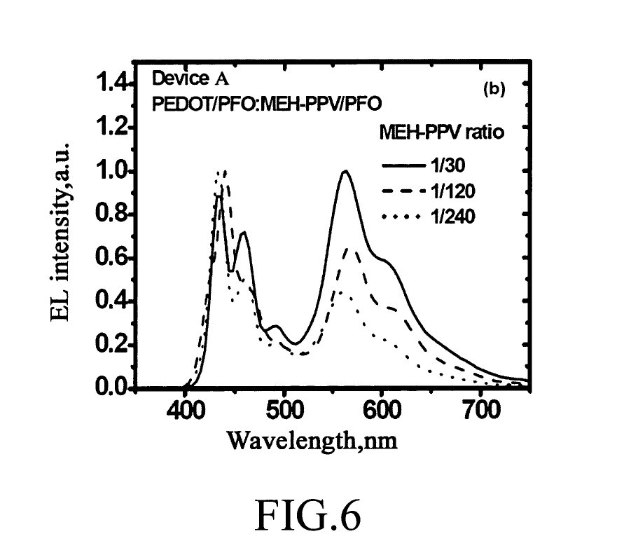

Please refer to FIG. 4, showing the second preferred embodiment of the invention. The organic light emitting composite 331 also includes two organic light emitting layers for example. Both of the first organic light emitting layer 340 and the second organic light emitting layer 350 use the same polymeric light emitting material with a higher energy gap as the host material. What is different from the first embodiment is that both of the first organic light emitting layer 340 and the second organic light emitting layer 350 are doped with polymeric light emitting materials with lower energy. For example, the polymeric light emitting host material can be a blue polymer light emitting material, the first organic light emitting layer can be doped with a reddish polymer light emitting material, and the second organic light emitting layer can be doped with a green polymer light emitting material such that the lights from the first organic light emitting layer 340 and the second organic light emitting layer 350 will mix and produce three-color white light.

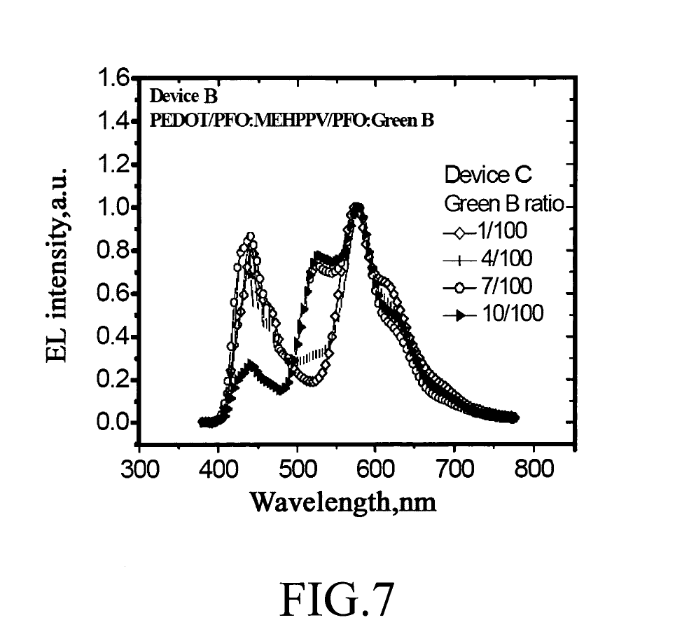

FIG. 5 shows the third preferred embodiment of the invention, which differs from the previous two embodiments in that the organic light emitting composite 331 includes three organic light emitting layers for example. All of the first organic light emitting layer 340, the second organic light emitting layer 350 and the third organic light emitting layer 360 use the same polymeric light emitting material with a higher energy gap as a host material. Both of the second organic light emitting layer 350 and the third organic light emitting layer 360 are doped with polymeric light emitting materials with lower energy. For example, the polymeric light emitting host material can be a blue polymer light emitting material and the first organic light emitting layer is not doped with any polymer light emitting material. The second light emitting layer 350 can be a blue-green polymer light emitting material doped with a lower energy gap. The third organic light emitting layer is doped with a reddish polymer light emitting material such that the lights from the first organic light emitting layer 340, the second organic light emitting layer 350 and the third organic light emitting layer 360 mix and produce three-color white light.

Although only two or three organic light emitting layers are used as examples in the embodiments, practically, the number of organic light emitting layers is not limited.

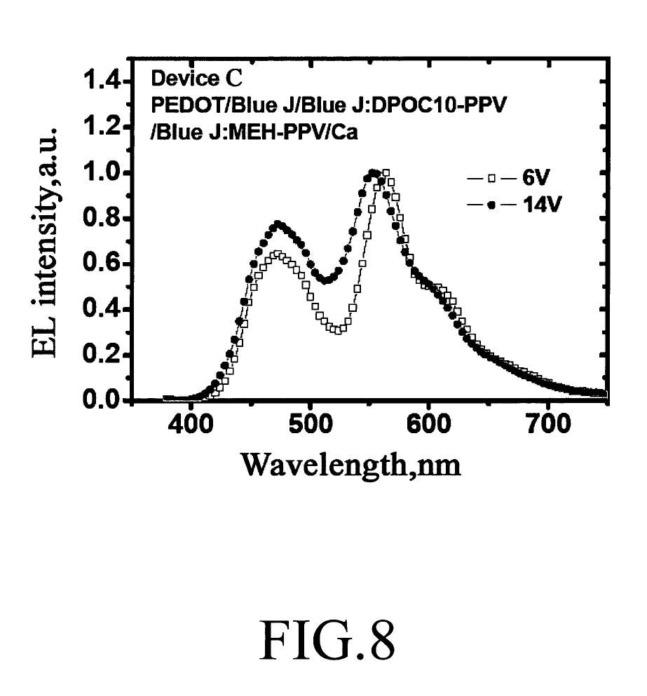

FIGS. 6 to 8 are the spectrums of the first working example, the second working example and the third working example, respectively. The colors, trade names and providers of polymeric light emitting materials are listed in the table below.

| Colors | Trade names | Providers |
|---|---|---|
| Red | Red B | Dow Chemical |
| Reddish | MEH-PPV | Dow Chemical |
| Yellow | Super yellow | Covion |
| Green | Green K2 | Dow Chemical |
| Blue-green | DPOC10-PPV | National Chiao-Tung University, |
| | | NCTU |
| Blue | BP 79, BP 105, Blue J, | Dow Chemical |
| | PFO | |

### THE FIRST WORKING EXAMPLE

The former steps of the process include: cleaning an ITO coated commercialized substrate by supersonic vibration; rinsing it in deionized water and drying; mixing a PFO and a MEH-PPV together with a proportion in xylene, wherein the PFO is a blue polymer host material and the MEH-PPV is a reddish polymer doping material. After a series of former steps, the process includes the following steps: spin-coating a hole transportation layer (such as PEDOT) on the ITO; using a solution of PFO polymer host material and MEH-PPV polymer doping material to spin-coat the first 50 nm organic light emitting layer on the hole transportation layer; oven drying it in a vacuum oven for 60 minutes; using a PFO polymer host material solution to spin-coat the second 30 nm organic light emitting layer on the first organic light emitting layer; oven drying it in a vacuum oven for 60 minutes; and evaporating Ca/Al negative electrodes on the composite light emitting layers.

A device A formed by the above process can produce 3000 cd/m² compensated white light as 10 volts voltage is applied. The luminescence spectrum and intensity of the device are shown in FIG. 6, wherein different curves represent different doping ratios of MEH-PPV (1/30, 1/120, 1/240).

### THE SECOND WORKING EXAMPLE

The former steps of the process include: cleaning an ITO coated commercialized substrate by supersonic vibration; rinsing in deionized water and drying; mixing a PFO and a MEH-PPV together with a proportion in xylene, wherein the PFO is a blue polymer host material and the MEH-PPV is a reddish polymer doping material; and mixing a PFO and a Green K2 together with a proportion in a solvent, wherein the Green K2 is a green polymer doping material. After a series of former steps, the process includes the following steps: spin-coating a hole transportation layer (such as PEDOT) on the ITO; using a solution of PFO polymer host material and MEH-PPV polymer doping material to spin-coat the first 50 nm organic light emitting layer on the hole transportation layer; oven drying it in a vacuum oven for 60 minutes; using a PFO polymer host material and a Green K2 polymer doping material solution to spin-coat the second 30 nm organic light emitting layer on the first organic light emitting layer; oven drying it in a vacuum oven for 60 minutes; and evaporating Ca/Al negative electrodes on the composite light emitting layers.

A device B formed by the above process can produce 1500 cd/m² three-color white light as 10 volts voltage is applied. The luminescence spectrum and intensity of the device are shown in FIG. 7, wherein different curves represent different doping ratios of Green K2 (1/100, 4/100, 7/100, 10/100).

### THE THIRD WORKING EXAMPLE

The former steps of the process include: cleaning an ITO coated commercialized substrate by supersonic vibration; rinsing in deionized water and drying; mixing a Blue J and a MEH-PPV together with a proportion in xylene, wherein the Blue J is a blue polymer host material and the MEH-PPV is a reddish polymer doping material; and mixing a Blue J and a DPOC10-PPV together with a proportion in xylene, wherein the DPOC10-PPV is a blue-green polymer doping material. After a series of former steps, the process includes the following steps: spin-coating a hole transportation layer (such as PEDOT) on the ITO; using a solution of Blue J polymer host material to spin-coat the first organic light emitting layer on the hole transportation layer; oven drying it in a vacuum oven for 60 minutes; using a Blue J polymer host material doped with DPOC10-PPV polymer material solution to spin-coat the second organic light emitting layer on the first organic light emitting layer; oven drying it in a vacuum oven for 60 minutes; using a Blue J polymer host material doped with MEH-PPV polymer material solution to spin-coat the third organic light emitting layer on the second organic light emitting layer; oven drying it in a vacuum oven for 60 minutes; and evaporating Ca/Al negative electrodes on the composite light emitting layers.

A device C formed by the above process has the luminescence spectrum and intensity shown in FIG. 8, wherein different curves represent different driving voltages (6V, 14V).

In summary, a polymeric LED device according to the invention provides higher luminescence of all colors.

The device B and device C can work with a color filter in a display to obtain desirable colors.

Next, because the polymeric LED device is formed by coating, it is convenient for display production, especially for large screen display production.

Although the invention has been described with reference to specific embodiments, this description is not meant to be construed in a limiting sense. Various modifications of the disclosed embodiments, as well as alternative embodiments, will be apparent to persons skilled in the art. It is, therefore, intended that the appended claims will cover all modifications that fall within the true scope of the invention.

What is claimed is:

1. A polymeric light emitting diode (PLED) device, comprising:
a substrate;
a positive electrode, which is formed above the substrate;
a hole transportation layer, which is formed above the positive electrode;
a organic light emitting composite layer which is formed above the hole transportation layer, comprising a plurality of organic light emitting layers, wherein every organic light emitting layer has a polymeric host material with higher energy gap, and at least one of the organic light emitting layers is doped with a polymeric doping material with lower energy gap; and
a negative electrode, which is formed above the organic light emitting composite layer.

2. The device of claim 1, wherein the substrate is a transparent substrate.

3. The device of claim 2, wherein the transparent substrate is selected from one group consisted of a glass, quartz, and a plastic.

4. The device of claim 1, wherein the substrate is an opaque substrate.

5. The device of claim 4, wherein the opaque substrate is consisted of a semiconductor material or a ceramic material.

6. The device of claim 1, wherein the positive electrode is selected from one group consisted of a metal oxide, a nitride, a selenide, and a sulphide.

7. The device of claim 6, wherein the metal oxide is selected from one group of a indium-tin oxide, a indium-zinc oxide, a aluminum-zinc oxide, a tin oxide, a magnesium-zinc oxide, a fluorine-tin oxide, a nickel-tungsten oxide and a cadmium-tin oxide.

8. The device of claim 1, wherein the positive electrode is selected from one group of a aurum, a iridium, a palladium, and a platinum.

9. The device of claim 1, wherein the hole transportation layer is consisted of a polymer conductive material.

10. The device of claim 1, wherein the polymeric host material with higher energy gap is a near blue polymeric material.

11. The device of claim 1, wherein the polymeric doping material with lower energy gap is a near red polymeric material.

12. The device of claim 1, wherein two of the organic light emitting layers have different polymeric doping materials with lower energy gap.

13. The device of claim 12, wherein one of the polymeric doping materials is a near red polymeric material and the other one of the polymeric doping materials is a near green polymeric material.

14. The device of claim 12, wherein the negative electrode is consisted of a Ca/Al or a Ca/Ag.

15. The device of claim 1, wherein three of the organic light emitting layers have the same polymeric host materials with higher energy gap and at least two of the organic light emitting layers have different polymeric doping materials with lower energy gap.

16. The device of claim 15, wherein the polymeric host material with higher energy gap is a near blue polymeric material.

17. The device of claim 16, wherein one of the polymeric doping materials with lower energy gap is a near green polymeric material.

18. The device of claim 17, wherein the other one of the polymeric doping materials with lower energy gap is a near red polymeric material.

19. The device of claim 1, wherein the organic light emitting layer with the polymeric host material with higher energy gap is formed by coating.

20. The device of claim 1, wherein the organic light emitting layer with the polymeric host material with higher energy gap and the polymeric doping material with lower energy gap is formed by coating.

21. A display using a polymeric light emitting diode (PLED) device, comprising:
a substrate;
a positive electrode, which is formed above the substrate;
a hole transportation layer, which is formed above the positive electrode;
a organic light emitting composite layer which is formed above the hole transportation layer, comprising a plurality of organic light emitting layers, wherein every organic light emitting layer has a polymeric host material with higher energy gap, and at least one of the organic light emitting layers is doped with a polymeric doping material with lower energy gap;
a negative electrode, which is formed above the organic light emitting composite layer; and
a color filter, which is formed above the substrate or the negative electrode for filtering a light produced by the organic light emitting composite layer and for penetrating a specific wavelength of light.
